(19) United States
(12) Patent Application Publication
(10) Pub. No.: US 2026/0293402 A1
(43) Pub. Date: Sep. 24, 2026

(54) LIGHT-EMITTING SUBSTRATE, LIGHT-EMITTING APPARATUS, AND DISPLAY APPARATUS

(71) Applicants: BOE MLED Technology Co., Ltd., Daxing District, Beijing (CN); BOE TECHNOLOGY GROUP CO., LTD., Beijing (CN)

(72) Inventors: Honghao Yu, Beijing (CN); Donglei Li, Beijing (CN); Yong Li, Beijing (CN); Jiaxin Li, Beijing (CN); Tonghua Yang, Beijing (CN); Dongdong Ma, Beijing (CN); Yufan Mu, Beijing (CN); Kun Lu, Beijing (CN)

(73) Assignees: BOE MLED Technology Co., Ltd., Daxing District, Beijing (CN); BOE TECHNOLOGY GROUP CO., LTD., Beijing (CN)

(21) Appl. No.: 19/472,182

(22) PCT Filed: May 17, 2024
(86) PCT No.: PCT/CN2024/093825

§ 371 Date: Oct. 3, 2025

(30) Foreign Application Priority Data
Jun. 8, 2023 (CN) 202310678784.2

(51) Int. Cl. H10H 29/85; H10H 29/851

(52) U.S. Cl. CPC H10H 29/8508; H10H 29/8514

(57) ABSTRACT

A light-emitting base plate, a light-emitting apparatus, and a display apparatus are provided by the present application, which relate to the technical field of displaying. The light-emitting base plate includes a substrate and a plurality of light-emitting devices arranged in an array and located on the substrate. The substrate includes an intermediate region and a surrounding region surrounding the intermediate region. The plurality of light-emitting devices include first light-emitting devices and second light-emitting devices. A half-power angle of each of the second light-emitting devices is set to be greater than a half-power angle of each of the first light-emitting devices. The intermediate region is only provided with the first light-emitting devices, and the surrounding region is provided with at least one of the second light-emitting devices. The light-emitting base plate is suitable for the fabrication of display apparatuses with narrow frames.

### CROSS-REFERENCE TO RELATED APPLICATION

The present application claims the priority of the Chinese patent application filed on Jun. 8, 2023 before the China National Intellectual Property Administration with the application number of 202310678784.2 and the title of “LIGHT-EMITTING SUBSTRATE, LIGHT-EMITTING APPARATUS, AND DISPLAY APPARATUS”, which is incorporated herein in its entirety by reference.

### FIELD

The present application relates to the technical field of displaying and, more particularly, to a light-emitting base plate, a light-emitting apparatus, and a display apparatus.

### BACKGROUND

With development of display technology, people have higher and higher requirements on picture quality and use performance of display products. In the display products in related art, in an area close to edges of the display products, a phenomenon of a decrease in brightness or a significant dimming often occurs in a display picture, which reduces a display effect.

### SUMMARY

The technical solutions below are adopted by the embodiments of the present application.

In a first aspect, a light-emitting base plate is provided by at least one embodiment of the present application, which includes:
a substrate including an intermediate region and a surrounding region surrounding the intermediate region;
a plurality of light-emitting devices arranged in an array and located on the substrate;
wherein the plurality of light-emitting devices include first light-emitting devices and second light-emitting devices; a half-power angle of each of the second light-emitting devices is set to be greater than a half-power angle of each of the first light-emitting devices; and the intermediate region is only provided with the first light-emitting devices, and the surrounding region is provided with at least one of the second light-emitting devices.

In at least one embodiment of the present application, the surrounding region has a closed outline; a size of the intermediate region along a first direction is X times a size of the surrounding region along the first direction, and a size of the intermediate region along a second direction is X times a size of the surrounding region along the second direction, wherein the first direction and the second direction intersect, and a value of X ranges from 7 to 8.

In at least one embodiment of the present application, the surrounding region is only provided with the second light-emitting devices; along the first direction, a distance between two adjacent first light-emitting devices is greater than or equal to a distance between two adjacent second light-emitting devices; and
along the second direction, a distance between the two adjacent first light-emitting devices is greater than or equal to a distance between the two adjacent second light-emitting devices.

In at least one embodiment of the present application, along the first direction, a distance between a first light-emitting device and a second light-emitting device that are adjacent is less than or equal to the distance between the two adjacent first light-emitting devices; and
along the second direction, a distance between the first light-emitting device and the second light-emitting device that are adjacent is less than or equal to the distance between the two adjacent first light-emitting devices.

In at least one embodiment of the present application, the surrounding region is only provided with the second light-emitting devices; along the first direction, a distance between two adjacent first light-emitting devices is less than or equal to a distance between two adjacent second light-emitting devices; and
along the second direction, a distance between the two adjacent first light-emitting devices is less than or equal to a distance between the two adjacent second light-emitting devices.

In at least one embodiment of the present application, along the first direction, a distance between a second light-emitting device closest to any one of edges of the substrate and the edge is not greater than the distance between the two adjacent first light-emitting devices; and along the second direction, a distance between a second light-emitting device closest to any one of edges of the substrate and the edge is not greater than the distance between the two adjacent first light-emitting devices.

In at least one embodiment of the present application, a brightness of the surrounding region is greater than or equal to 70% of a brightness of the intermediate region.

In at least one embodiment of the present application, a brightness difference between the surrounding region and the intermediate region is less than 0.04×107 Lux.

In at least one embodiment of the present application, the surrounding region and the intermediate region include an integer number of light regions, respectively, and each light region includes a×b electrically connected light-emitting devices, wherein a and b are positive integers.

In at least one embodiment of the present application, the surrounding region and the intermediate region include a non-integer number of light regions, respectively, and each light region includes axb electrically connected light-emitting devices, wherein a and b are positive integers.

In a second aspect, a light-emitting apparatus is provided by the embodiments of the present application, which includes the light-emitting base plate according to any one of embodiments in a first aspect.

In at least one embodiment of the present application, the light-emitting apparatus further includes a diffusing plate, a quantum dot film, a diffusion sheet and a composite film sequentially arranged in layer configuration;
wherein the diffusing plate is located at a light-exiting side of the light-emitting base plate.

In a third aspect, a display apparatus is provided by the embodiments of the present application, the display apparatus includes a display plate and the light-emitting apparatus as stated in the second aspect, the display plate is located at a light-exiting side of the light-emitting apparatus, and light emitted by all the light-emitting devices in the light-emitting apparatus has a same color.

The above description is only an overview of the technical solution of the present application, in order to be able to better understand the technical means of the present application, and the solution can be implemented in accordance with the content of the description, and in order to make the above and other purposes, features and advantages of the present application more obvious and easier to understand, the following specific embodiments of the present application are hereby given.

### BRIEF DESCRIPTION OF THE DRAWINGS

In order to more clearly illustrate the technical solutions of the embodiments of the present application or the related art, the drawings that are required to be used in the description of the embodiments or the related art will be briefly introduced below. Apparently, the drawings that are described below are only some embodiments of the present application, and a person skilled in the art can obtain other drawings according to these drawings without paying any creative work.

FIG. 1 is a schematic diagram of light superposition in a light-emitting base plate in related art according to an embodiment of the present application;

FIG. 2 is a schematic structural diagram of a cross-section taken along a section line M1-M2 in FIG. 1;

FIG. 3 is a schematic structural diagram of a cross-section of a light-emitting base plate according to an embodiment of the present application;

FIG. 4 is a comparison diagram of diffusion distances of light emitted by a first light-emitting device and a second light-emitting device according to an embodiment of the present application;

FIG. 5A and FIG. 5B are top-view structural schematic diagrams of two arrangements of a surrounding region and an intermediate region according to an embodiment of the present application;

FIG. 6 is a schematic diagram of different light-emitting angles and light intensity distributions of a second light-emitting device according to an embodiment of the present application;

FIG. 7 is a schematic diagram of different light-emitting angles and light intensity distributions of a first light-emitting device according to an embodiment of the present application;

FIG. 8 to FIG. 10 are top-view structural schematic diagrams of four light-emitting base plates according to an embodiment of the present application;

FIG. 11 is a schematic structural diagram of a cross-section taken along a section line M3-M4 in FIG. 10;

FIG. 12 is a schematic structural diagram of a cross-section of a light-emitting apparatus according to an embodiment of the present application;

FIG. 13 is a schematic structural diagram of a cross-section of a display apparatus according to an embodiment of the present application;

FIG. 14 is a top-view structural diagram of a display image of a light-emitting apparatus prepared by using a light-emitting base plate in related art according to an embodiment of the present application;

FIG. 15 is a brightness curve measured along a horizontal direction of the display image in FIG. 14;

FIG. 16 is a brightness curve measured along a vertical direction of the display image in FIG. 14;

FIG. 17 is a top-view structural diagram of a display image of a light-emitting apparatus prepared by using a light-emitting base plate according to an embodiment of the present application;

FIG. 18 is a brightness curve measured along a horizontal direction of the display image in FIG. 17; and

FIG. 19 is a brightness curve measured along a vertical direction of the display image in FIG. 17.

### DETAILED DESCRIPTION

The technical solutions of the embodiments of the present application will be clearly and completely described below with reference to the drawings of the embodiments of the present application. Apparently, the described embodiments are merely a part of embodiments of the present application, rather than all of the embodiments. All of the other embodiments that a person skilled in the art obtains on the basis of the embodiments of the present application without paying any creative work fall within the protection scope of the present application.

In the embodiments of the present application, terms such as “first”, “second”, “third” and “fourth” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, the terms that indicate orientation or position relations, such as “upper” and “lower”, are based on the orientation or position relations shown in the drawings, and are merely for conveniently describing the present application and simplifying the description, rather than indicating or implying that the device or element must have the specific orientation and be constructed and operated according to the specific orientation. Therefore, they should not be construed as a limitation on the present application.

In the description of the present application, the terms “one embodiment”, “some embodiments”, “exemplary embodiment”, “example”, “specific example” or “some examples” are intended to indicate that specific features, structures, materials or characteristics related to the embodiment or example are included in at least one embodiment or example of the present application. The schematic indication of the above terms does not necessarily refer to the same one embodiment or example. Moreover, the specific features, structures, materials or characteristics may be included in any one or more embodiments or examples in any suitable manner.

In the embodiments of the present application, the meaning of “plurality of” is “two or more”, and the meaning of “at least one” is “one or more”, unless explicitly and particularly defined otherwise.

All of the features used in the embodiments of the present application of “parallel”, “perpendicular”, “the same” and so on include the features of “parallel”, “perpendicular”, “the same” and so on in the strict sense, and include the cases in which there is a certain tolerance such as “substantially parallel”, “substantially perpendicular” and “substantially the same”, taking into consideration the measurement and the tolerances relevant to the measurement on particular quantities (for example, restricted by the measuring system), and represent that they are in the acceptable deviation ranges of the particular values determined by a person skilled in the art. For example, the “substantially” can represent that they are within one or more standard deviations, or within 10% or 5% of the values.

Unless stated otherwise in the context, throughout the description and the claims, the term “include” is interpreted as the meaning of opened containing, i.e., “including but not limited to”

The polygons in the description are not the strictly defined polygons, may be an approximate triangle, parallelogram, trapezoid, pentagon, hexagon and so on, and may have some small deformations caused by tolerance.

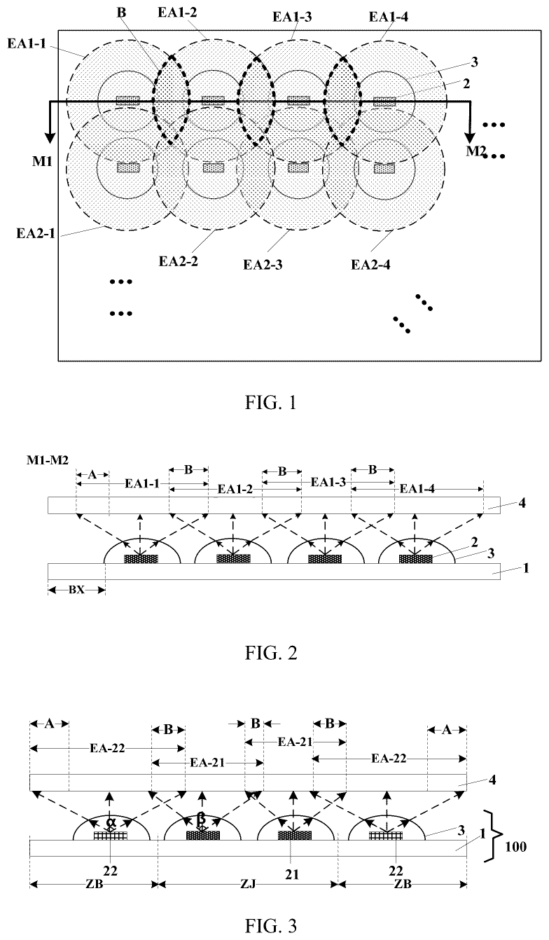

Referring to FIG. 1 and FIG. 2, wherein FIG. 2 is a schematic structural diagram of a cross-section taken along a section line M1-M2 in FIG. 1, dashed arrows in FIG. 2 represent propagation paths of light. The light emitted by a light-emitting device 2 may refract at the interface of an encapsulation unit 3 to modulate a light-emitting range of the light-emitting device. Specifically, the light-emitting base plate is provided with a plurality of light-emitting devices 2, the light-emitting devices 2 may be mini light emitting diodes (Mini LEDs). The lighted regions of a first row of light-emitting devices 2 on an optical film layer 4 are sequentially arranged from left to right as a lighted region EA1-1, a lighted region EA1-2, a lighted region EA1-3, a lighted region EA1-4, and so on. For each independent light-emitting device 2, a brightness of light emitted by the light-emitting device 2 in a region facing a geometric center of the light-emitting device 2 on the optical film layer is greater than a brightness of light emitted by the light-emitting device 2 in a region away from a geometric center of the light-emitting device 2 in the optical film layer. For the non-edge region of the optical film layer 4, such as the light-emitting devices 2 corresponding to the lighted region EA1-2 and the lighted region EA1-3, respectively, and, although the brightness of the light emitted by each of the light-emitting devices in the region facing the geometric center of the light-emitting device 2 on the optical film layer is greater than the brightness of the light emitted by each of the light-emitting devices in the region away from the geometric center of the light-emitting device 2 on the optical film layer, the lighted regions of two adjacent light-emitting devices 2 on the optical film layer 4 overlap (i.e., a region B in FIG. 2), which can alleviate a phenomenon of the uneven brightness of a single light-emitting device existed in different regions of the optical film layer 4. For the light-emitting device 2 corresponding to the lighted region EA1-1, it is closest to the edge region of the optical film layer 4, and the brightness of the light emitted by the light-emitting device 2 in the region close the edge of the optical film layer 4 is weaker than the brightness of the light emitted by the light-emitting device 2 in the region of facing the geometric center of the light-emitting device 2 on the optical film layer. The light in the region close to the edge of the optical film layer 4 does not overlap with the lighted regions of any other light-emitting devices 2 on the optical film layer 4 (i.e., a region A of FIG. 2). Therefore, in the case of using the above light-emitting base plate to provide surface light source, a phenomenon that the brightness of the edge of the light-emitting base plate is lower than the brightness of the intermediate region causes the edge to be darkened, reduces the brightness uniformity, and reduces the user experience.

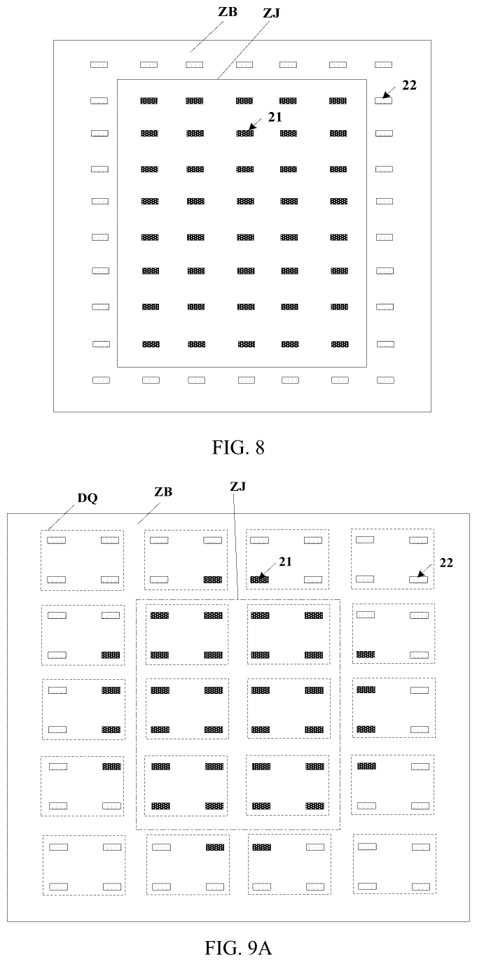

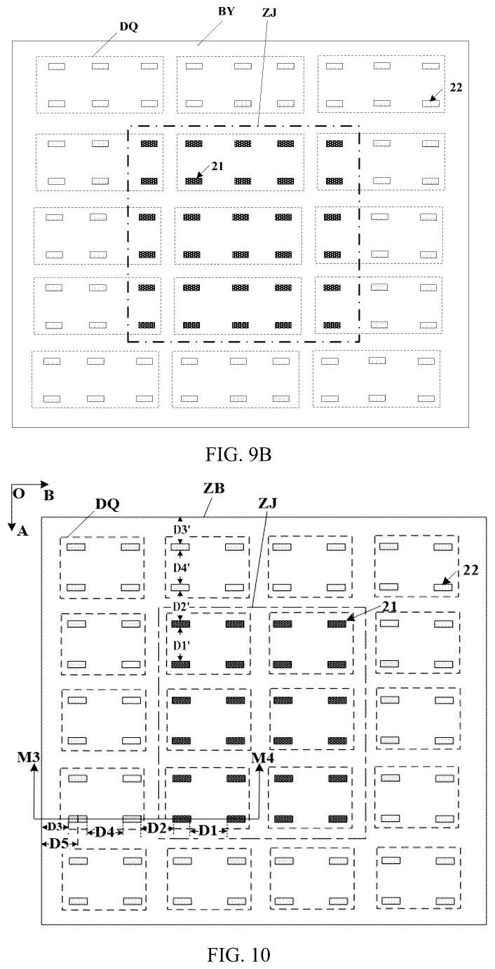

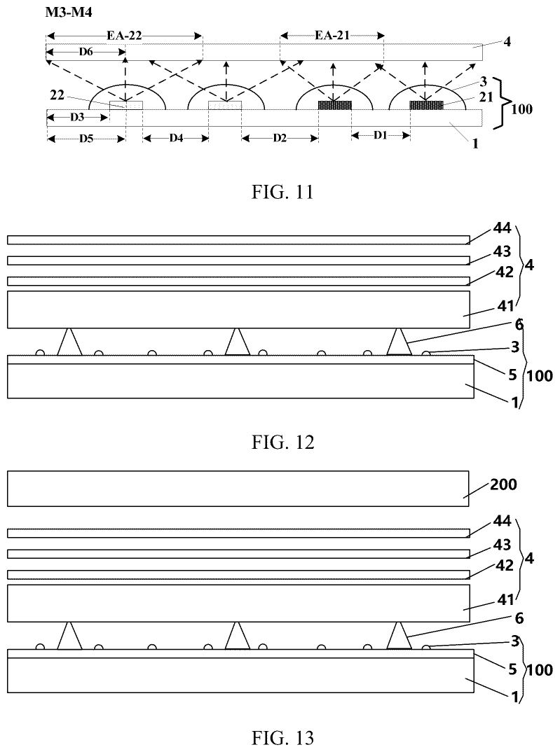

Based on this, a light-emitting base plate 100 is provided by at least one embodiment of the present application, as shown in FIG. 3. The light-emitting base plate 100 includes:
a substrate 1 including an intermediate region ZJ and a surrounding region ZB surrounding the intermediate region;
a plurality of light-emitting devices 2 arranged in an array and located on the substrate 1;
wherein the plurality of light-emitting devices 2 include first light-emitting devices 21 and second light-emitting devices 22; a half-power angle of each of the second light-emitting devices 22 is set to be greater than a half-power angle of each of the first light-emitting devices 21; and referring to FIG. 8, FIG. 9A, FIG. 9B, FIG. 10 and FIG. 11, the intermediate region ZJ is only provided with the first light-emitting devices 21, and the surrounding region ZB is provided with at least one of the second light-emitting devices 22.

FIG. 11 is a schematic structural diagram of a cross-section taken along a section line M-3-M-4 in FIG. 10.

It should be noted that the optical film layer 4 shown in FIG. 3 and FIG. 11 is only used to illustrate the position of a light-receiving surface of the light-emitting base plate 100 and to describe the diffusion distances of the light-emitting devices 2, and the light-emitting base plate does not include the optical film layer 4.

In an exemplary embodiment, the substrate 1 may be a rigid substrate, and a material of the rigid substrate may be any one of glass, quartz, PET and plastic. A thickness of the rigid substrate may range from 0.2 mm to 1 mm. For example, the thickness of the rigid substrate may be 0.2 mm, 0.4 mm, 0.5 mm, 0.7 mm, or 1 mm.

In an exemplary embodiment, the light-emitting base plate 100 may include a plurality of light regions DQ arranged in an array, and each light region DQ includes at least one light-emitting device 2.

Here, the quantity of light regions DQ included by the light-emitting base plate 100 may be not limited. For example, when the light-emitting base plate 100 is applied to small-sized display products such as mobile phones, smartwatches, or computer screens, the light-emitting base plate 100 may include 9 light regions, 16 light regions, or 25 light regions. When the light-emitting base plate 100 is applied to large-sized display products such as televisions or outdoor display screens, the light-emitting base plate 100 may include dozens, hundreds, or even thousands of light regions, such as 1,440 light regions. The specific quantity can be determined based on actual application requirements.

In an exemplary embodiment, for each light region DQ in the light-emitting base plate 100, the status of the light region DQ can be individually controlled, for example, a light region DQ can be independently controlled to be in an illuminated state or an extinguished state; or a brightness of the light region DQ can also be independently controlled, for example, the brightness of the light region DQ may be independently controlled to be increased or decreased.

In an exemplary embodiment, one light region DQ can include one light-emitting device 2 to achieve independent control of each light-emitting device 2; or, one light region DQ can include multiple light-emitting devices 2, for example, one light region DQ can include 4 light-emitting devices 2, 6 light-emitting devices 2 or 9 light-emitting devices 2, and all of the light-emitting devices 2 in the same light region DQ can be controlled by the same micro-drive chip.

In an exemplary embodiment, the light-emitting device 2 stated above may be a Mini Light Emitting Diode (abbreviated as Mini LED) or a micro light emitting diode (abbreviated as Micro LED), which is not limited herein.

In addition, except for the light-emitting devices 2, the light-emitting base plate 100 may also be provided with other components such as any one of a sensor device, a micro-drive chip, or other types of devices. It can be understood that the quantities of different types of devices are different, or that the densities of the array arrangements of different types of devices are different. The light-emitting device 2, the sensor device, the micro-drive chip or other types of devices mentioned above are collectively referred to as devices.

In an exemplary embodiment, each light region DQ may be provided with one micro-drive chip. The light-emitting base plate 100 can control the overall light-emitting brightness of the light regions DQ via the micro-drive chips to achieve a partition control function (such as local dimming) of the light-emitting base plate 10.

In some embodiments, the micro-drive chips may be disposed at the same side of substrate 1 as the light-emitting devices 2. In other embodiments, the light-emitting devices 2 may be disposed at one side of the substrate 1, the micro-drive chips are disposed at the other side of the substrate 1. When the light-emitting devices 2 and the micro-drive chips are disposed at two sides of the substrate 1, the design space of the light-emitting base plates 100 can be significantly saved, which is beneficial for the fabrication of the light-emitting base plates 100 with a larger quantity of partitions.

Apart from the light-emitting performance, the types of the first light-emitting devices 21 and the second light-emitting devices 22 are the same. For example, both the first light-emitting devices 21 and the second light-emitting devices 22 are mini light emitting diodes (abbreviated as Mini LEDs). For another example, both the first light-emitting devices 21 and the second light-emitting devices 22 are micro light-emitting diodes (abbreviated as Micro LEDs).

Exemplarily, the plurality of light-emitting devices 2 may all be mini light emitting diodes or micro light-emitting diodes that emit blue light, or light-emitting devices 2 can simultaneously include three types of light-emitting diodes or micro light-emitting diodes that emit red light, green light and blue light.

In the light-emitting base plate provided by the embodiments of the present application, the light-emitting performance of the first light-emitting device 21 differs from the light-emitting performance of the second light-emitting device 22. The light-emitting performance of the first light-emitting device 21 and the light-emitting performance of the second light-emitting device 22 include, but are not limited to: a light-emitting intensity, a light pattern of the emitted light, a diffusion angle of the light, and a diffusion distance of the light. The light-emitting intensity is related to a size of a driving current, and can be specifically determined based on a designed value of the driving current.

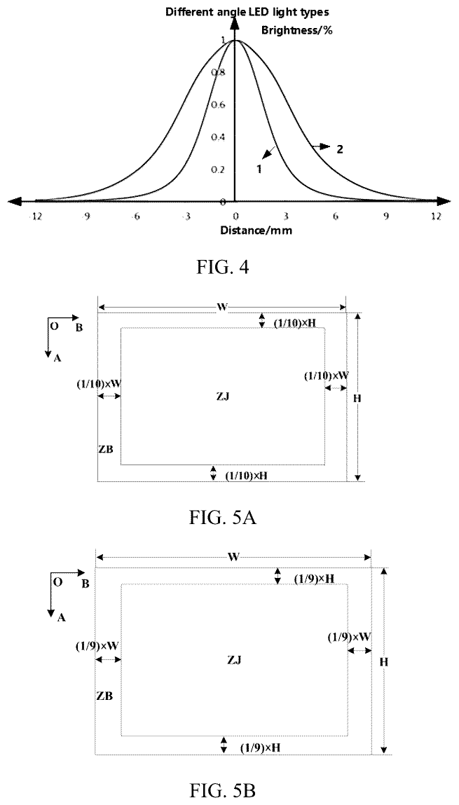

Exemplarily, as shown in FIG. 4, a comparison of the light patterns of light emitted by the first light-emitting device 21 and the second light-emitting device 22 is shown. In FIG. 4, a curve labeled by 1 represents a light pattern curve of the first light-emitting device 21, and a curve labeled by 2 represents a light pattern curve of the second light-emitting device 22. An abscissa in FIG. 4 represents a diffusion distance of the light after the light is emitted, along a direction perpendicular to the light emitted at a positive visual angle. An ordinate in FIG. 4 represents a percentage of the light-emitting intensity (brightness). From FIG. 4, it can be seen that at the same brightness, a diffusion distance of the first light-emitting device 21 is significantly less than a diffusion distance of the second light-emitting device 22, and a full width at half maxima (about 8 mm) of a light diffusion curve of the second light-emitting device 22 is significantly greater than a full width at half maxima (about 4 mm) of the first light-emitting device 21.

It should be noted that data of the brightness of the ordinate in FIG. 4 is data after being normalization processed, which does not represent that the brightness of the light emitted by the first light-emitting device 21 and the brightness of the light emitted by the second light-emitting device 22 are the same when the diffusion distance is 0 mm (at a positive visual angle), nor does it represent that when the diffusion distance is greater than 0 mm, the brightness of the light emitted by the first light-emitting device 21 is less than the brightness of the light emitted by the second light-emitting device 22. The light-emitting intensity is related to the size of the driving current, which can be determined based on a designed value of the driving current.

In an exemplary embodiment, the diffusion distance of the light is directly proportional to the diffusion angle of the light, i.e., the greater the diffusion distance of the light, the greater the diffusion angle of the light.

A half-power angle of the second light-emitting device 22 is set to be greater than a half-power angle of the first light-emitting device 21. The power angle is also known as the light-emitting angle. In the industry, the half-power angle is commonly used to characterize a performance of a light-emitting device. The half-power angle refers to the angle corresponding to the point where the light-emitting intensity of a light-emitting device is half of its maximum light-emitting intensity.

Exemplarily, the larger the half-power angle of the light-emitting device 2, the greater the diffusion distance of the emitted light of the light-emitting device 2.

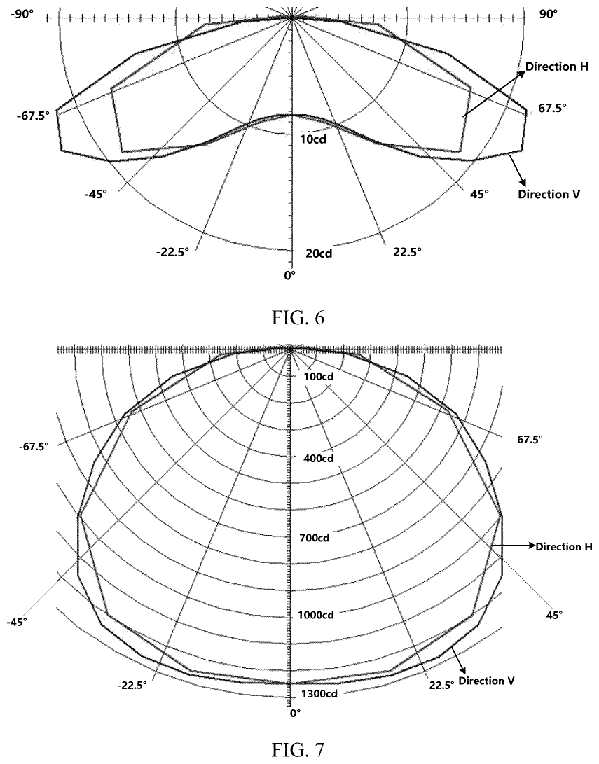

In an exemplary embodiment, as shown in FIG. 6, which shows a schematic diagram of different light-emitting angles and light intensity distributions of a second light-emitting device along a direction H and a direction V, wherein the direction H and the direction V are two mutually perpendicular directions passing through the geometric center of the second light-emitting device 22. From FIG. 6, it can be seen that regardless of the direction H or the direction V, a brightness of the second light-emitting device 22 when an absolute value of a visual angle is less than 45®is less than a brightness of the second light-emitting device 22 when the absolute value of the visual angle is greater than 45°. It should be noted that in FIG. 6, in a curve labeled by the direction H, 45°and −45 ° respectively represent brightness distribution situations at a visual angle of 45° at a left side and a visual angle of 45° at a right side. In the curve labeled by the direction V, 45°+and −45 °respectively represent the brightness distribution situations at a visual angle of 45° at an upper side and a visual angle of 45° at a lower side.

In an exemplary embodiment, as shown in FIG. 7, which shows a schematic diagram of different light-emitting angles and light intensity distributions of a first light-emitting device 21 along a direction H and a direction V, wherein the direction H and the direction V are two mutually perpendicular directions passing through the geometric center of the first light-emitting device 21. From FIG. 7, it can be seen that regardless of the direction H or the direction V, a brightness of the first light-emitting device 21 when an absolute value of a visual angle is less than 45° is greater than a brightness of the first light-emitting device 21 when the absolute value of the visual angle is greater than 45°. It should be noted that in FIG. 7, in a curve labeled by the direction H, 45° and −45 ° respectively represent brightness distribution situations at a visual angle of 45° at a left side and at a visual angle of 45° at a right side. In the curve labeled by the direction V, 45° and −45 ° respectively represent the brightness distribution situations at a visual angle of 45° at an upper side and at a visual angle of 45° at a lower side.

That the intermediate region ZJ is only provided with the first light-emitting devices 21, and the surrounding region ZB is provided with at least one of the second light-emitting devices 22 includes but not limited to the following situations:

Firstly, the surrounding region ZB is only provided with the second light-emitting devices 22.

Of course, it can be understood that in some embodiments, the surrounding region ZB refers to the edge region of the substrate 1 closest to the light-emitting base plate 100, and Y rows of light-emitting devices 2 closest to the edge of the light-emitting base plate are all second light-emitting devices, wherein Y is a positive integer greater than or equal to 1. For the case where the light-emitting devices are arranged on the substrate in an array, the above “row” includes rows and/or columns. For example, as shown in FIG. 8, in some embodiments, the light-emitting devices 2 located on the substrate 1 and closest to the edge of the light-emitting base plate 100 are all second light-emitting devices 22, that is, Y=1. For the case where light-emitting devices are arranged in an array on the substrate, that is, the first row, the last row, the first column, and the last column of light-emitting devices are the second light-emitting devices. For another example, in some embodiments, for the light region where the light-emitting devices 2 located on the substrate 1 and closest to the edge of the light-emitting base plate 100 is located, and the light-emitting devices within the light region are all second light-emitting devices. As shown in FIG. 10, every 2×2 light-emitting devices 2 form a light region, and the light region closest to the edge of the light-emitting base plate 100 is all provided with the second light-emitting devices 22.

Secondly, in the surrounding region ZB, not only the second light-emitting devices 22 are disposed, but also the first light-emitting devices 21 are disposed. Exemplarily, in the surrounding region ZB, a top corner position of the two adjacent edges close to the light-emitting base plate 100 is provided with at least one second light-emitting device 22, and a position of the surrounding region ZB parallel to a certain edge of the light-emitting base plate 100 and close to the intermediate region ZJ can be provided with a first light-emitting device 21. As shown in FIG. 9A, the two rows of light-emitting devices 2 closest to the edge of the light-emitting base plate are located in the surrounding region ZB, wherein the light-emitting devices in the first row, the last row, the first column, and the last column are all the second light-emitting devices 22, and in the light-emitting devices in the second row, the second-to-last row, the second column, and the second-to-last column, the light-emitting device that is closer to a geometric center of the substrate 1 is a second light-emitting device 22.

In at least one embodiment of the present application, as shown in FIG. 3, the light-emitting base plate 100 further includes multiple encapsulation units 3 corresponding to devices (including but not limited to the light-emitting devices 2). The orthographic projection of each encapsulation unit 3 on the substrate 1 covers the orthographic projection of the device (e.g., the light-emitting device 2) on the substrate 1.

Exemplarily, each encapsulation unit 3 encapsulates one device (e.g., the light-emitting device 2). While playing a role in encapsulation protection for the device (e.g., the light-emitting device 2), the encapsulation unit 3 can further modulate the light-emitting angle of the light-emitting device 2 by designing a shape of a surface of the encapsulation unit 3 away from the substrate 1, for example, making a surface of the encapsulation unit 3 to be a convex lens-like surface.

In some embodiments, the light-emitting base plate 100 may further include an encapsulation layer disposed at the side of the device (e.g., the light-emitting device 2) away from the substrate 1, and the encapsulation layer is configured to protect the device (e.g., the light-emitting device 2).

Exemplarily, the encapsulation layer may be a whole layer covering the plurality of light-emitting devices 2.

In some embodiments, the light-emitting base plate may also include a reflecting layer 5 as shown in FIG. 12. The reflecting layer 5 is located on the substrate 1 and has a plurality of hollow regions along a direction perpendicular to the substrate 1, and the device (e.g., the light-emitting device 2) is disposed within the hollow regions.

Since the light emitted by light-emitting device 2 radiates in all directions, the reflecting layer 5 can reflect the light emitted by the light-emitting device 2 onto a light-emitting surface of the light-emitting base plate 100 to improve the light utilization rate of the light-emitting device 2.

Exemplarily, a color of the reflecting layer 5 is white to make that the reflecting layer 5 has a high reflectivity.

In some embodiments, the reflecting layer 5 may be a sheet-like structure with multiple hollow regions, or the reflecting layer 5 may also be formed on the light-emitting base plate 100 via processes such as sputtering, coating film, or depositing.

Exemplarily, a material of the reflecting layer 5 may include white ink, and a component of the white ink includes resins (e.g., epoxy or polytetrafluoroethylene resin), titanium dioxide (the chemical formula of titanium dioxide is TiO₂), and organic solvents (e.g., dipropylene glycol methyl ether).

Exemplarily, the material of the reflecting layer 5 may also include silicone-based white adhesive. When the material of the reflecting layer 5 includes white ink or silicone-based adhesive, the silk screen printing process can be used to print and form the reflecting layer 5, or the adhesive-valve spray coating process can be used to spray and coat to form the reflecting layer 5.

Exemplarily, the reflecting layer 5 may be fabricated through single silk screen printing process or multiple silk screen printing processes.

When the multiple silk screen printing processes are used to fabricate the reflecting layer 5, the portion of the reflecting layer 5 located at the edge of the hollow region can be in a stepped shape.

Exemplarily, an orthographic projection of the hollow region on the substrate 1 may be circular, triangular, rectangular, etc.

In the light-emitting base plate provided by the embodiment of the present application, by setting that the plurality of light-emitting devices 2 include the first light-emitting devices 21 and the second light-emitting devices 22; a half-power angle of each of the second light-emitting devices 22 is set to be greater than a half-power angle of each of the first light-emitting devices 21; and the intermediate region ZJ of the substrate 1 of the light-emitting base plate 100 is only provided with the first light-emitting devices 21, and the surrounding region ZB is provided with at least one of the second light-emitting devices 22. In this way, when the light-emitting base plate 100 is applied to the light-emitting apparatus, the brightness at the edge of the light-emitting apparatus can be increased, the uniformity of the brightness of the light emitted by the light-emitting apparatus is improved, thereby the problem of dark edges is alleviated and the display effect is improved.

In at least one embodiment of the present application, as shown in FIG. 3, an area of a light-emitting region EA-21 of the first light-emitting device 21 on the reference surface (for example, a surface of the optical film layer 4 close to the substrate 1) is less than an area of a light-emitting region EA-22 of the second light-emitting device 22 on the reference surface. The reference surface is located at a light-emitting side of the light-emitting device 2 and is parallel to a plane where the substrate 1 is located. The half-power angle β of the first light-emitting device 21 is less than the half-power angle a of the second light-emitting device 22.

Exemplarily, the half-power angle β of the first light-emitting device 21 is less than or equal to 140°.

Exemplarily, the half-power angle a of the second light-emitting device 22 is greater than 140° and less than 180°. For example, the half-power angle α of the second light-emitting device 22 is greater than 150° and less than or equal to 170°. Specifically, the half-power angle α of the second light-emitting device 22 can be 155°, 158°, 160°, 162°, 164°, 165°, 168°, or 170°.

In the embodiments of the present application, by setting at least one circle of light-emitting devices 2 located on the substrate 1 and close to the edges of the light-emitting base plate as the second light-emitting devices 22, the area of the light-emitting region EA-21 of the first light-emitting device 21 on the reference surface (for example, the surface of the optical film layer 4 close to the substrate 1) is less than the area of the light-emitting region EA-22 of the second light-emitting device 22 on the reference surface, and the half-power angle β of the first light-emitting device 21 is less than the half-power angle α of the second light-emitting device 22. In this way, when the light-emitting base plate 100 is applied to the light-emitting apparatus, the brightness at the edge of the light-emitting apparatus can be enhanced, the uniformity of the brightness of light emitted by the light-emitting apparatus can be improved, thereby the problem of dark edges is alleviated and the display effect is improved.

In at least one embodiment of the present application, as shown in FIG. 5A and FIG. 5B, the surrounding region ZB of the light-emitting base plate 100 has a closed outline, and the outline of the surrounding region is similar to the planar outline of the substrate base plate. A size of the intermediate region ZJ along a first direction (for example, a vertical direction OA) is X times a size of the surrounding region along the first direction (for example, the vertical direction OA), and a size of the intermediate region ZJ along a second direction (for example, a horizontal direction OB) is X times a size of the surrounding region along the second direction (for example, the horizontal direction OB), wherein the first direction (for example, the vertical direction OA) and the second direction (for example, the horizontal direction OB) intersect, and a value of X ranges from 7 to 8.

Exemplarily, X can take values of 7, 7.3, 7.5, 7.8, and 8.

Exemplarily, as shown in FIG. 5A, X is equal to 8, a width of the surrounding region ZB along the first direction (for example, the vertical direction OA) is (1/10)×H, a width of the intermediate region ZJ along the first direction (for example, the vertical direction OA) is (8/10)×H, and the width of the intermediate region ZJ along the first direction (for example, the vertical direction OA) is 8 times the width of the surrounding region along the first direction. The width of the surrounding region ZB along the second direction (for example, the horizontal direction OB) is (1/10)×H, the width of the intermediate region ZJ along the second direction (for example, the horizontal direction OB) is (8/10)×H, and the width of the intermediate region ZJ along the second direction (for example, the horizontal direction OB) is 8 times the width of the surrounding region ZB along the second direction.

For example, as shown in FIG. 5B, X is equal to 7, and the width of the surrounding region ZB along the first direction (for example, the vertical direction OA) is (1/9)×H, the width of the intermediate region ZJ along the first direction (for example, the vertical direction OA) is (7/9)×H, and the width of the intermediate region ZJ along the first direction (for example, the vertical direction OA) is 7 times the width of the surrounding region along the first direction. The width of the surrounding region ZB along the second direction (for example, the horizontal direction OB) is (1/9)×H, the width of the intermediate region ZJ along the second direction (for example, the horizontal direction OB) is (7/9)×H, and the width of the intermediate region ZJ along the second direction (for example, the horizontal direction OB) is 7 times the width of the surrounding region ZB along the second direction.

In an exemplary embodiment, the more the quantity of the light regions DQ in the light-emitting base plate 100, the smaller the size of the light-emitting device 2, and the smaller the spacing between two adjacent light-emitting devices 2. Then, the quantity of the light regions DQ in the surrounding region ZB is also greater, and the quantity of the second light-emitting devices 22 in the surrounding region ZB is also greater.

Exemplarily, at least one circle of the second light-emitting devices 22 are disposed in the surrounding region ZB of the light-emitting base plate 100.

Exemplarily, at least one circle of the light regions DQ are disposed in the surrounding region ZB of the light-emitting base plate 100, and all the light-emitting devices 2 included by the light region DQ in the surrounding region ZB are the second light-emitting devices 22.

Here, the quantity of the second light-emitting devices 22 disposed in the surrounding region ZB stated above is not limited. The quantity of the second light-emitting devices 22 disposed in the surrounding region ZB stated above can be specifically determined according to the quantity of the light regions DQ in the light-emitting base plate 100 and the distribution density of the light-emitting devices 2.

In at least one embodiment of the present application, as shown in FIG. 8 and FIG. 10, the light-emitting base plate 100 includes an intermediate region ZJ and a surrounding region ZB surrounding the intermediate region ZJ, wherein the surrounding region ZB is only provided with the second light-emitting devices 22 and the intermediate region ZJ is only provided with the first light-emitting devices 21.

In the embodiments of the present application, by setting that the surrounding region ZB is only provided with the second light-emitting devices 22 and the intermediate region ZJ is only provided with the first light-emitting devices 21, in this way, when the light-emitting base plate 100 is applied to the light-emitting apparatus, the brightness at the edge of the light-emitting apparatus can be enhanced, the uniformity of the brightness of light emitted by the light-emitting apparatus can be improved, thereby the problem of dark edges of the light-emitting apparatus is alleviated and the display effect is improved.

In at least one embodiment of the present application, as shown in FIG. 8 and FIG. 10, the surrounding region ZB is only provided with the second light-emitting devices 22. As shown in FIG. 10, along the first direction (for example, the vertical direction OA), a distance D1′ between two adjacent first light-emitting devices 21 is greater than or equal to a distance D4′ between two adjacent second light-emitting devices 22. Along the second direction (for example, the horizontal direction OB), a distance D1 between the two adjacent first light-emitting devices 21 is greater than or equal to a distance D4 between the two adjacent second light-emitting devices 22.

In practical applications, it can be set that along the first direction (for example, the vertical direction OA), the distance D1′ between the two adjacent first light-emitting devices 21 is greater than or equal to the distance D4′ between the two adjacent second light-emitting devices 22, and along the second direction (for example, the horizontal direction OB), the distance D1 between the two adjacent first light-emitting devices 21 is greater than or equal to the distance D4 between the two adjacent second light-emitting devices 22. In this way, a distribution density of the second light-emitting devices 22 located in the surrounding region ZB can be set to be greater than or equal to a distribution density of the first light-emitting devices 21 located in the intermediate region ZJ. Thus, the light-emitting brightness of the light-emitting base plate located in the surrounding region ZB can be further improved, the brightness of the edge of the light-emitting apparatus is improved, the uniformity of the brightness of light emitted by the light-emitting apparatus is improved, thereby the problem of dark edges of the light-emitting apparatus is alleviated and the display effect is improved.

In at least one embodiment of the present application, as shown in FIG. 10, along the first direction (for example, the vertical direction OA), the distance D2′ between the first light-emitting device 21 and the second light-emitting device 22, which are adjacent at a junction position of the surrounding region ZB and the intermediate region, is less than or equal to the distance D1′ between the two adjacent first light-emitting devices 21. Along the second direction (for example, the horizontal direction OB), the distance D2 between the first light-emitting device 21 and the second light-emitting device 22, which are adjacent at the junction position of the surrounding region ZB and the intermediate region, is less than or equal to the distance D1 between the two adjacent first light-emitting devices 21.

Exemplarily, along the first direction (for example, the vertical direction OA), the distance D2′ between the first light-emitting device 21 and the second light-emitting device 22, which are adjacent at the junction position of the surrounding region ZB and the intermediate region, is less than the distance Dl′ between the two adjacent first light-emitting devices 21. Along the second direction (for example, the horizontal direction OB), the distance D2 between the first light-emitting device 21 and the second light-emitting device 22, which are adjacent at the junction position of the surrounding region ZB and the intermediate region, is less than the distance D1 between the two adjacent first light-emitting devices 21.

Exemplarily, along the first direction (for example, the vertical direction OA), the distance D2′ between the first light-emitting device 21 and the second light-emitting device 22, which are adjacent at the junction position of the surrounding region ZB and the intermediate region, is equal to the distance D1′ between the two adjacent first light-emitting devices 21. Along the second direction (for example, the horizontal direction OB), the distance D2 between the first light-emitting device 21 and the second light-emitting device 22, which are adjacent at the junction position of the surrounding region ZB and the intermediate region, is equal to the distance D1 between the two adjacent first light-emitting devices 21.

It should be noted that in the embodiment of the present application shown in FIG. 10, it is illustrated by taking the case as an example, where along the first direction (for example, the vertical direction OA), the distance D2′ between the first light-emitting device 21 and the second light-emitting device 22, which are adjacent at the junction position of the surrounding region ZB and the intermediate region, is equal to the distance DI′ between the two adjacent first light-emitting devices 21, and along the second direction (for example, the horizontal direction OB), the distance D2 between the first light-emitting device 21 and the second light-emitting device 22, which are adjacent at the junction position of the surrounding region ZB and the intermediate region, is equal to the distance D1 between the two adjacent first light-emitting devices 21.

In the embodiments of the present application, by setting that in the light-emitting base plate, along the first direction (for example, the vertical direction OA), the distance D2′ between the first light-emitting device 21 and the second light-emitting device 22, which are adjacent at the junction position of the surrounding region ZB and the intermediate region ZJ, is less than the distance DI′ between the two adjacent first light-emitting devices 21; and along the second direction (for example, the horizontal direction OB), the distance D2 between the first light-emitting device 21 and the second light-emitting device 22, which are adjacent at the junction position of the surrounding region ZB and the intermediate region, is less than the distance D1 between the two adjacent first light-emitting devices 21; in this way, the light-emitting devices 2 can be disposed as close as possible to the intermediate region ZJ, so that when the light-emitting base plate 100 is applied in the display apparatus, the size of the peripheral frame of the display apparatus can be minimized as much as possible, which is conducive to the fabrication of a narrow-frame display apparatus.

In the embodiments of the present application, by setting that in the light-emitting base plate, along the first direction (for example, the vertical direction OA), the distance D2′ between the first light-emitting device 21 and the second light-emitting device 22, which are adjacent at the junction position of the surrounding region ZB and the intermediate region ZJ, is equal to the distance D1′ between the two adjacent first light-emitting devices 21; and along the second direction (for example, the horizontal direction OB), the distance D2 between the first light-emitting device 21 and the second light-emitting device 22, which are adjacent at the junction position of the surrounding region ZB and the intermediate region, is equal to the distance D1 between the two adjacent first light-emitting devices 21; in this way, on the basis of improving the problem of surrounding dimming, all the light-emitting devices 2 can be made to be uniformly distributed, which is more conducive to the fabrication of the driving circuit in the light-emitting base plate 100, the difficulty of the fabrication process can be reduced and the cost is reduced.

In at least one embodiment of the present application, as shown in FIG. 8 and FIG. 10, the surrounding region ZB is only provided with the second light-emitting devices 22.

Exemplarily, as shown in FIG. 10, along the first direction (for example, the vertical direction OA), a distance D1′ between the two adjacent first light-emitting devices 21 is less than or equal to a distance D4′ between the two adjacent second light-emitting devices 22.

Exemplarily, as shown in FIG. 10, along the second direction (for example, the horizontal direction OB), the distance D1 between the two adjacent first light-emitting devices 21 is less than or equal to the distance D4 between the two adjacent second light-emitting devices 22.

It should be noted that in FIG. 8 and FIG. 10 provided by the embodiments of the present application, FIG. 8 and FIG. 10 are drawn by taking the case as an example where along the first direction (for example, the vertical direction OA), the distance D1′ between the two adjacent first light-emitting devices 21 is equal to the distance D4′ between the two adjacent second light-emitting devices 22; and along the second direction (for example, the horizontal direction OB), the distance D1 between the two adjacent first light-emitting devices 21 is equal to the distance D4 between the two adjacent second light-emitting devices 22.

In the embodiments of the present application, since a diffusion angle of the second light-emitting device 22 is greater than a diffusion angle of the first light-emitting device 21, and a diffusion distance of the second light-emitting device 22 is greater than a diffusion distance of the first light-emitting device 21, it may be set that along the first direction (for example, the vertical direction OA), the distance D1′ between the two adjacent first light-emitting devices 21 is less than or equal to the distance D4′ between the two adjacent second light-emitting devices 22; and along the second direction (for example, the horizontal direction OB), the distance D1 between the two adjacent first light-emitting devices 21 is less than or equal to the distance D4 between the two adjacent second light-emitting devices 22. In this way, the distribution density of the second light-emitting devices 22 located in the surrounding region ZB can be set to be less than the distribution density of the first light-emitting devices 21 located in the intermediate region ZJ, thereby the cost of the light-emitting base plate 100 is reduced.

When the brightness of the light-receiving surface of the surrounding region ZB of the light-emitting base plate 100 is low and insufficient to improve the problem of dark edges, by the partition control function of the light-emitting base plate 100, the brightness of the second light-emitting device 22 located in the light regions DQ of the surrounding region ZB can be controlled to be greater than or equal to the brightness of the first light-emitting device 21 located in the light region DQ of the intermediate region ZJ, to compensate for the light loss caused by the larger diffusion angle and larger diffusion distance of the second light-emitting device 22. When the light-emitting base plate 100 is applied to the light-emitting apparatus, the brightness of the surrounding region ZB and the intermediate region ZJ corresponding to the light-emitting apparatus tends to be consistent, the uniformity of the brightness of the light emitted by the light-emitting apparatus is improved, thereby the problem of dark edges of the light-emitting apparatus is improved and the display effect is improved.

In the present specification, the reference surface and the light-receiving surface both refer to the light projection surface of the light-emitting base plate 100 after the light is emitted. In the present specification, that the reference surface and the light-receiving surface are the optical film layer 4 is taken as an example for illustration.

In at least one embodiment of the present application, as shown in FIG. 10, along the first direction (for example, the vertical direction OA), a distance D3′ between a second light-emitting device 22 closest to any one of edges of the substrate 1 and the edge is not greater than a distance D1′ between the two adjacent first light-emitting devices 21; and as shown in FIG. 10 and FIG. 11, along the second direction (for example, the horizontal direction OB), a distance D3 between a second light-emitting device closest to any one of edges of the substrate 1 and the edge is not greater than a distance D1 between the two adjacent first light-emitting devices 21.

Here, the phrase “not greater than” includes cases of less than or equal to.

Exemplarily, along the first direction (for example, the vertical direction OA), the distance D3′ between the second light-emitting device 22 closest to any one of edges of the substrate 1 and the edge is equal to the distance D1′ between the two adjacent first light-emitting devices 21; and along the second direction (for example, the horizontal direction OB), the distance D3 between the second light-emitting device 22 closest to any one of edges of the substrate 1 and the edge is equal to the distance D1 between the two adjacent first light-emitting devices 21.

Exemplarily, along the first direction (for example, the vertical direction OA), the distance D3′ between the second light-emitting device 22 closest to any one of edges of the substrate 1 and the edge is less than the distance DI′ between the two adjacent first light-emitting devices 21; and along the second direction (for example, the horizontal direction OB), the distance D3 between the second light-emitting device 22 closest to any one of edges of the substrate 1 and the edge is less than the distance D1 between the two adjacent first light-emitting devices 21.

In the light-emitting base plate 100 provided by the embodiments of the present application, by setting that along the first direction (for example, the vertical direction OA), the distance D3′ between the second light-emitting device 22 closest to any one of edges of the substrate 1 and the edge is not greater than the distance D1′ between the two adjacent first light-emitting devices 21; and along the second direction (for example, the horizontal direction OB), the distance D3 between the second light-emitting device 22 closest to any one of edges of the substrate 1 and the edge is not greater than the distance D1 between the two adjacent first light-emitting devices 21, in this way, the distance between the light-emitting device 2 and the edge of the substrate 1 can be made to be relatively small, which is more conducive to the fabrication of products with narrow frames.

In at least one embodiment of the present application, referring to FIG. 10 and FIG. 11, along the horizontal direction OB, the distance D5 between a center of the second light-emitting device 22 closest to any one of the edges of the substrate 1 and the edge is less than or equal to half of a plane size D6 of the light-emitting region EA-22 of the second light-emitting device 22 on the reference surface (for example, the surface of the optical film layer 4 close to the substrate 1) along the horizontal direction OB. The center of the second light-emitting device 22 refers to the geometric center of the second light-emitting device 22.

In at least one embodiment of the present application, along the vertical direction OA, the distance between the center of the second light-emitting device 22 closest to any one of the edges of the substrate 1 and the edge is less than or equal to half of a plane size of the light-emitting region EA-22 of the second light-emitting device 22 on the reference surface (for example, the surface of the optical film layer 4 close to the substrate 1) along the horizontal direction OB.

In the embodiments of the present application, by setting that the distance D5 between the center of the second light-emitting device 22 closest to any one of the edges of the substrate 1 and the edge is less than or equal to half of a plane size D6 of the light-emitting region EA-22 of the second light-emitting device 22 on the reference surface (for example, the surface of the optical film layer 4 close to the substrate 1) along the horizontal direction OB, in this way, the light emitted by the second light-emitting device 2 closest to the edge of the light-emitting base plate 100 can be projected onto the edge of the reference surface. When the light-emitting base plate 100 is applied to the light-emitting apparatus, the brightness of the edge of the light-emitting apparatus can be improved, the uniformity of the brightness of the light emitted by the light-emitting apparatus is improved, thereby the problem of dark edges of the light-emitting apparatus is alleviated and the display effect is improved.

In at least one embodiment of the present application, a brightness of the surrounding region is greater than or equal to 70% of a brightness of the intermediate region.

It should be noted that the brightness of the surrounding region ZB and the brightness of the intermediate region ZJ mentioned above both refer to an average brightness.

Exemplarily, the brightness of the surrounding region ZB is greater than or equal to 70% to 90% of the brightness of the intermediate region ZJ. For example, the brightness of the surrounding region ZB is 75%, 80%, 85%, 88%, 90%, 92%, 94%, or 95% of the brightness of the intermediate region ZJ.

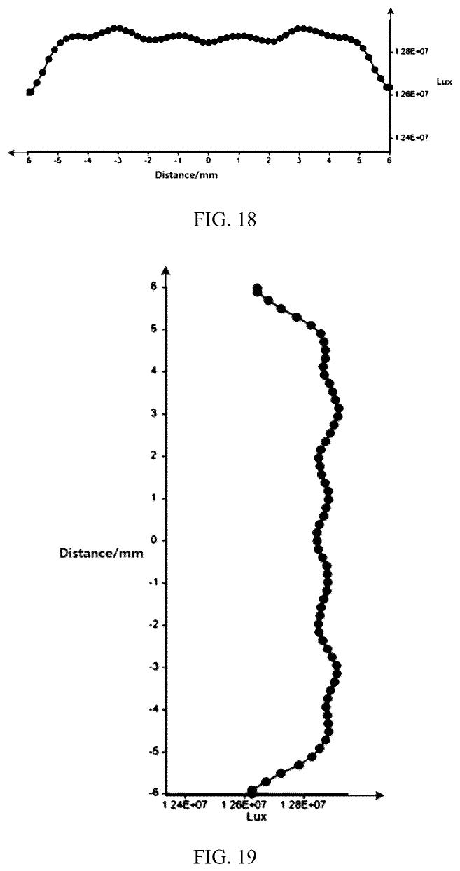

In at least one embodiment of the present application, as shown in FIG. 17, FIG. 18, and FIG. 19, the brightness difference between the surrounding region ZB and the intermediate region ZJ is less than 0.04×10⁷ Lux.

FIG. 17 is a top-view structural diagram of a display image of a light-emitting apparatus prepared by using a light-emitting base plate provided by the present application. FIG. 18 is a brightness curve measured along a horizontal direction of the display image in FIG. 17; and FIG. 19 is a brightness curve measured along a vertical direction of the display image in FIG. 17.

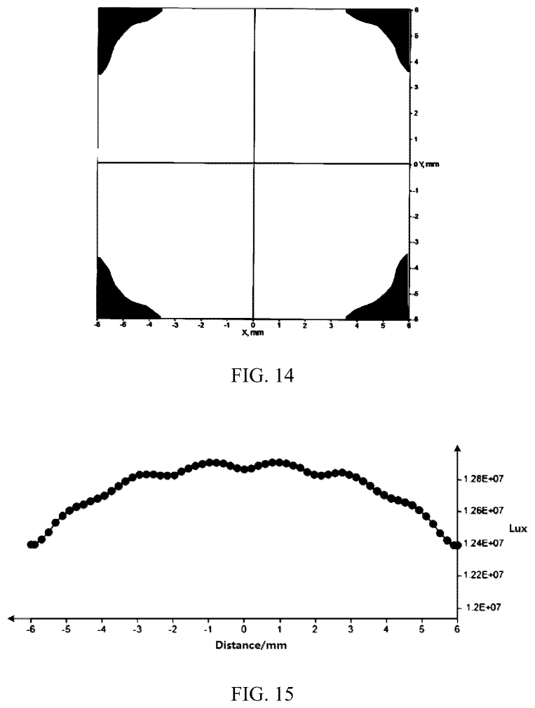

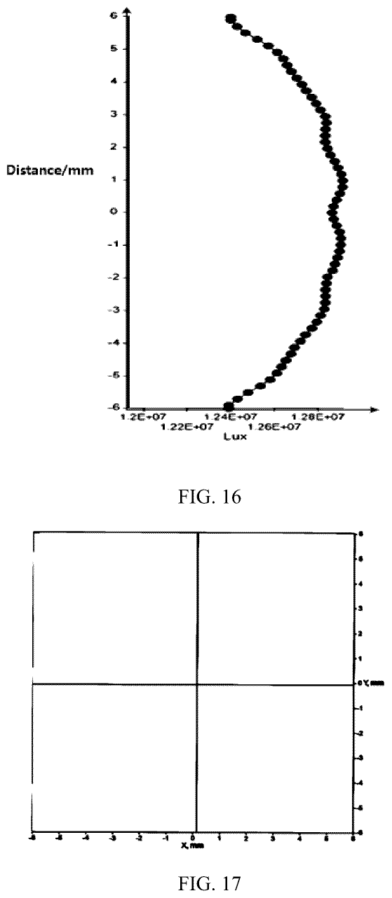

FIG. 14 provides a top-view structural diagram of a display image of a light-emitting apparatus prepared by using a light-emitting base plate in related art. FIG. 15 is a brightness curve measured along a horizontal direction of the display image in FIG. 14; and FIG. 16 is a brightness curve measured along a vertical direction of the display image in FIG. 14.

By combining FIG. 14, FIG. 15, and FIG. 16, it can be seen that the edge of the display image of the light-emitting apparatus prepared by using the light-emitting base plate in the related art has obvious dimming phenomena, and the brightness difference between the middle of the display image and the edge of the display image is approximately 0.05×10⁷Lux. By contrast, by combining FIG. 17, FIG. 18, and FIG. 19, it can be seen that the dimming phenomenon at the edge of the display image of the light-emitting apparatus prepared by using the light-emitting base plate provided by the present application is significantly improved, and the brightness difference between the middle of the display image and the edge of the display image is less than 0.04×10⁷Lux.

In at least one embodiment of the present application, as shown in FIG. 8 and FIG. 10, the surrounding region ZB is only provided with the second light-emitting devices 22, and the intermediate region ZJ is only provided with the first light-emitting devices 21. The surrounding region ZB and the intermediate region ZJ include an integer number of light regions DQ, respectively, and each light region DQ includes a×b electrically connected light-emitting devices 2, wherein a and b are positive integers.

It can be understood that when the surrounding region ZB is only provided with the second light-emitting devices 22, and the intermediate region ZJ is only provided with the first light-emitting devices 21; and the surrounding region ZB and the intermediate region ZJ include an integer number of light regions DQ, respectively, the first light-emitting devices 21 and the second light-emitting devices 22 are respectively located in different light regions DQ.

In an exemplary embodiment, the light-emitting base plate 100 further includes a plurality of micro-drive chips. The plurality of micro-drive chips include the first micro-drive chip and the second micro-drive chip. The first micro-drive chip is electrically connected to the first light-emitting device 21, and the second micro-drive chip is electrically connected to the second light-emitting device 22.

In the light-emitting base plate provided by the embodiments of the present application, the first light-emitting device 21 and the second light-emitting device 22 are independently controlled, respectively. That is, the first light-emitting device 21 is controlled by using the first micro-drive chip, and the second light-emitting device 22 is controlled by using the second micro-drive chip. In this way, it is realized that the first light-emitting device 21 and the second light-emitting device 22 can be independently controlled. By using the two types of micro-drive chips (the first micro-drive chip and the second micro-drive chip), the brightness of the second light-emitting devices 22 in one circle of the light regions DQ disposed close to the edges of the light-emitting base plate 100 is controlled to be greater than the brightness of other first light-emitting devices 21, thus when the light-emitting base plate 100 is applied to the light-emitting apparatus, the brightness of the edge of the light-emitting apparatus can be further improved, the uniformity of the brightness of the light emitted by the light-emitting apparatus is improved, thereby the problem of dark edges is alleviated and the display effect is improved.

In an exemplary embodiment, as shown in FIG. 8, a light region DQ includes a light-emitting device 2. In the surrounding region ZB, all the light-emitting devices 2 in one circle of the light regions DQ disposed close to the edges of the light-emitting base plate 100 are the second light-emitting devices 22.

In at least one embodiment of the present application, as shown in FIG. 10, all the light-emitting devices 2 in at least one circle of the light regions DQ disposed close to the edges of the light-emitting base plate 100 are the second light-emitting devices 22. “At least one circle of light regions” includes one circle of light regions DQ and two or more circles of light regions DQ.

In the embodiments of the present application, by setting that all the light-emitting devices 2 in at least one circle of the light regions DQ disposed close to the edges of the light-emitting base plate 100 are the second light-emitting devices 22, in this way, all the light-emitting devices 2 in one circle of the light regions DQ disposed close to the edges of the light-emitting base plate 100 are the second light-emitting devices 22, that is, all the light-emitting devices 2 within the same light region DQ are the second light-emitting devices 22. Since the light-emitting devices 2 within the same light region DQ are simultaneously controlled and driven, it is convenient for the partition control and driving of the light regions DQ in the light-emitting base plate 100.

In an exemplary embodiment, when all the light-emitting devices 2 in one circle of the light regions DQ disposed close to the edges of the light-emitting base plate 100 are the second light-emitting devices 22, by the partition control function of the light-emitting base plate 100, the brightness of the second light-emitting devices 22 in one circle of the light regions DQ disposed close to the edges of the light-emitting base plate 100 can be controlled to be greater than the brightness of other first light-emitting devices 21, thus when the light-emitting base plate 100 is applied to the light-emitting apparatus, the brightness of the edge of the light-emitting apparatus can be further improved, the uniformity of the brightness of the light emitted by the light-emitting apparatus is improved, thereby the problem of dark edges is alleviated and the display effect is improved.

In at least one embodiment of the present application, as shown in FIG. 9B, the surrounding region ZB is only provided with the second light-emitting devices 22, and the intermediate region ZJ is only provided with the first light-emitting devices 21. A quantity of the light regions DQ included by the surrounding region ZB and the intermediate region ZJ is not an integer.

Each light region DQ includes axb electrically connected light-emitting devices 2, wherein both a and b are positive integers.

It can be understood that when the surrounding region ZB is only provided with the second light-emitting devices 22, and the intermediate region ZJ is only provided with the first light-emitting devices 21, the surrounding region ZB and the intermediate region ZJ may include a non-integer number of light regions, respectively, as shown in FIG. 9B, there are some light regions DQ including both the first light-emitting devices 21 and the second light-emitting devices 22. Exemplarily, as shown in FIG. 9B, in one circle of the light regions DQ disposed close to the edges of the light-emitting base plate 100, the first row, the second row, the last but one row, and the last but two row of light-emitting devices 2 are all second light-emitting devices 22. That is, the light-emitting devices 2 in the first row of the light regions DQ and the last but one row of the light regions DQ are the second light-emitting devices 22. In the surrounding region ZB, except for the first row of the light regions DQ and the last but one row of the light regions DQ, the light-emitting devices 2 in the other light regions DQ can include both the first light-emitting devices 21 and the second light-emitting devices 22.

In practical applications, for the case where both the first light-emitting device 21 and the second light-emitting device 22 are included in the same light region DQ, it is also possible to dispose different driving channels in the micro-drive chip corresponding to the same light region DQ to provide different currents to the first light-emitting device 21 and the second light-emitting device 22 within the same light region DQ, thus it is realized that the first light-emitting device 21 and the second light-emitting device 22 in the same light region DQ are independently controlled. In this way, in the same light region DQ, the brightness of the second light-emitting device 22 can be controlled to be greater than the brightness of the first light-emitting device 21, thus when the light-emitting base plate 100 is applied to the light-emitting apparatus, the brightness of the edge of the light-emitting apparatus can be further improved, the uniformity of the brightness of the light emitted by the light-emitting apparatus is improved, thereby the problem of dark edges is alleviated and the display effect is improved.

In at least one embodiment of the present application, the light-emitting base plate 100 includes N×M light regions DQ, each light region DQ includes a×b electrically connected light-emitting devices 2. In the intermediate region ZJ, one first micro-drive chip is electrically connected to all the first light-emitting devices 21 in at least one light region DQ; N≥10, M≥10,1≤a≤5,1≤b≤5.

Exemplarily, each light region DQ includes a×b electrically connected light-emitting devices 2.

For example, each light region DQ includes: 1×1 light-emitting device 2, 1×2 electrically connected light-emitting devices 2, 2×2 electrically connected light-emitting devices 2, 3×3 electrically connected light-emitting devices 2, 4×4 electrically connected light-emitting devices 2, 4×5 electrically connected light-emitting devices 2, or 5×5 electrically connected light-emitting devices 2. Here, “electrically connected” includes series connection, parallel connection, and combinations of series connection and parallel connection.

In an exemplary embodiment, the light-emitting base plate 100 can also include a buffer layer, a first electrically conducting layer, an inter-layer medium layer, and a reflecting layer 5, which are sequentially arranged in layer configuration and located on the substrate 1. The inter-layer medium layer includes a first insulation layer and a first planarization layer, and the first electrically conducting layer is configured to form a conductive pattern. When there is sufficient space on the substrate 1 to arrange all the conductive patterns, the light-emitting base plate can only include one layer of the conductive layer.

Exemplarily, the material of the first electrically conducting layer can include any one of copper, aluminum, nickel, molybdenum, and titanium, or a combination of several metals arranged in layer configuration.

Exemplarily, the first electrically conducting layer can include a MoNiTi alloy layer, a copper metal layer, and a MoNb alloy layer, the MoNiTi alloy layer can increase the nucleation density of copper metal grains in the electroplating process, and the MoNb alloy layer plays a role in preventing the oxidation of copper metal. A thickness of the MoNiTi alloy layer in the first electrically conducting layer ranges from 290 Å to 310 Å, for example, the thickness of the MoNiTi alloy layer in the first electrically conducting layer can be 290 Å, 296 Å, 300 Å, 305 Å or 310 Å;

Exemplarily, a thickness of the first electrically conducting layer ranges from 1.5 μm to 7 μm, for example, the thickness of the first electrically conducting layer can be 1.5 μm, 2 μm, 4 μm, 6.5 μm or 7 μm.

In an exemplary embodiment, the light-emitting base plate can also include a buffer layer, a second electrically conducting layer, a second insulation layer, a second planarization layer, a third insulation layer, a first electrically conducting layer, an inter-layer medium layer, and a reflecting layer 5, which are sequentially arranged in layer configuration and located on the substrate 1. The first electrically conducting layer and the second electrically conducting layer together form the conductive pattern. The first electrically conducting layer is disposed farther away from the substrate 1 compared to the second electrically conducting layer.

Exemplarily, the material of the second electrically conducting layer can include any one of copper, aluminum, nickel, molybdenum, and titanium, or a combination of several metals arranged in layer configuration.

Exemplarily, the second electrically conducting layer can include a molybdenum-niobium alloy layer, a copper metal layer, and a protection layer sequentially arranged in layer configuration. The protection layer can include any one of copper-nickel alloy (CuNi), nickel, or indium tin oxide (ITO). The molybdenum-niobium alloy layer plays the role of enhancing the adhesion between the copper metal and the film layer close to the substrate, and the protection layer plays the role in preventing the copper metal from being oxidized.

Exemplarily, a thickness of the second electrically conducting layer ranges from 0.5 μm to 10 μm, for example, the thickness of the second electrically conducting layer can be 0.5 μm, 1 μm, 1.8 μm, 2.7 μm, or 10 μm.

In some embodiments, the light-emitting base plate 100 may further include a plurality of support columns 6 as shown in FIG. 12. The support column 6 is located at the side of the reflecting layer 5 away from the substrate 1, and an orthographic projection of the support column 6 on the substrate 1 does not overlap with an orthographic projection of the light-emitting device 2 on the substrate 1.

It should be noted that the color of the support column 6 can be selected as needed. For example, the color of the support column 6 can be white to make the reflectivity of the support column 6 close to the reflectivity of the reflecting layer 5. For another example, the support column 6 can be transparent.

A light-emitting apparatus is provided by the embodiments of the present application, as shown in FIG. 12, the light-emitting apparatus includes the light-emitting base plate 100 as described above.

The specific layers and components of the light-emitting base plate 100 can be referred to the illustration in the foregoing text, and will not be repeated here.

In some embodiments, the light-emitting apparatus may further include a protecting substrate (or a cover plate) covering the light-emitting base plate 100.

The light-emitting apparatus can be used as a backlight device, or can also be used as a display apparatus. Specifically, if the plurality of light-emitting devices 2 in the light-emitting apparatus are light-emitting devices 2 emitting light of a single color, then the light-emitting apparatus stated above can be used as a backlight device. If the plurality of light-emitting devices 2 in the light-emitting apparatus include light-emitting devices that emit different colors of light, such as red light, green light, and blue light, then the above light-emitting apparatus can be used as a display apparatus.

In some embodiments, when the light-emitting base plate 100 is used in a display apparatus, the support column 6 may not be set in the light-emitting base plate 100.

In at least one embodiment of the present application, as shown in FIG. 12, the light-emitting apparatus also includes a diffusing plate 41, a quantum dot film 42, a diffusion sheet 43, and a composite film 44, which are sequentially arranged in layer configuration. The diffusing plate 41 is located at the light-emitting side of the light-emitting base plate 100.

The plurality of support columns 6 are used to support the plurality of optical film layers 4 (including the diffusing plate 41, the quantum dot film 42, the diffusion sheet 43 and the composite film 44), to make that there is a mixed light distance between the reflecting layer 5 in the light-emitting base plate 100 and the optical film layer. The light shadow produced by the light-emitting base plate may be improved and the display quality of the light-emitting apparatus is improved.

In some embodiments, the material of the diffusing plate 41 can include glass, polystyrene (PS), polycarbonate (PC), polyethylene (PE), polypropylene (PP), polyvinyl chloride (PVC), polyethylene glycol terephthalate (PET), acrylic (PMMA), or methacrylic acid (MMA).

Specifically, the quantum dot film 42 (Quantum Dot Enhancement Films, abbreviated as QDEF) is a technology that uniformly mixes quantum dot fluorescent powder with a polymer to form a film. Exemplarily, the material of the quantum dot film 42 can include perovskite quantum dot materials, with a thickness generally around 100 μm.

In some embodiments, the material of the diffusion sheet 43 can be the same as the material of the diffusing plate 41.

In some embodiments, the composite film 44 is used to enhance the light efficiency while also serving as a protective film of the diffusing plate 41, the quantum dot film 42, and the diffusion sheet 43, providing protection to prevent scratches or damage.

A display apparatus is provided by the embodiments of the present application, as shown in FIG. 13. The display apparatus includes a display plate 200 and the light-emitting apparatus described above. The display plate 200 is located at the light-exiting side of the light-emitting apparatus, and the colors of the light emitted by all the light-emitting devices 2 in the light-emitting apparatus are the same.

The display plate 200 can be a liquid crystal display (LCD) plate, exemplarily, the liquid crystal display plate can include a twisted nematic (TN) type, a vertical alignment (VA) type, an in-plane switching (IPS) type and an advanced super dimension switch (ADS) type.

In the display apparatus provided by the embodiments of the present application, by setting that the light-emitting device 2 includes the first light-emitting devices 21 and the second light-emitting devices 22, the half-power angle of the second light-emitting device 22 is configured to be greater than the half-power angle of the first light-emitting device 21; and the intermediate region ZJ of the substrate 1 of the light-emitting base plate 100 is only provided with the first light-emitting devices 21, and the surrounding region ZB is provided with at least one second light-emitting device 22. In this way, the brightness of the edge of the light-emitting apparatus can be improved, the uniformity of the brightness of the light emitted by the light-emitting apparatus can be enhanced, thereby the problem of dark edges is improved and the display effect is improved.

The above are merely particular embodiments of the present application, and the protection scope of the present application is not limited thereto. All of the variations or substitutions that a person skilled in the art can easily envisage within the technical scope disclosed by the present application should fall within the protection scope of the present application. Therefore, the protection scope of the present application should be subject to the protection scope of the claims.

1. A light-emitting base plate, comprising:
a substrate comprising an intermediate region and a surrounding region surrounding the intermediate region;
a plurality of light-emitting devices arranged in an array and located on the substrate;
wherein the plurality of light-emitting devices comprise first light-emitting devices and second light-emitting devices; a half-power angle of each of the second light-emitting devices is set to be greater than a half-power angle of each of the first light-emitting devices; and
the intermediate region is only provided with the first light-emitting devices, and the surrounding region is provided with at least one of the second light-emitting devices.

2. The light-emitting base plate according to claim 1, wherein the surrounding region has a closed outline; a size of the intermediate region along a first direction is X times a size of the surrounding region along the first direction, and a size of the intermediate region along a second direction is X times a size of the surrounding region along the second direction, wherein the first direction and the second direction intersect, and a value of X ranges from 7 to 8.

3. The light-emitting base plate according to claim 2, wherein the surrounding region is only provided with the second light-emitting devices; along the first direction, a distance between two adjacent first light-emitting devices is greater than or equal to a distance between two adjacent second light-emitting devices; and
along the second direction, a distance between the two adjacent first light-emitting devices is greater than or equal to a distance between the two adjacent second light-emitting devices.

4. The light-emitting base plate according to claim 3, wherein along the first direction, a distance between a first light-emitting device and a second light-emitting device that are adjacent is less than or equal to the distance between the two adjacent first light-emitting devices; and
along the second direction, a distance between a first light-emitting device and a second light-emitting device that are adjacent is less than or equal to the distance between the two adjacent first light-emitting devices.

5. The light-emitting base plate according to claim 2, wherein the surrounding region is only provided with the second light-emitting devices; along the first direction, a distance between two adjacent first light-emitting devices is less than or equal to a distance between two adjacent second light-emitting devices; and
along the second direction, a distance between the two adjacent first light-emitting devices is less than or equal to a distance between the two adjacent second light-emitting devices.

6. The light-emitting base plate according to claim 3, wherein along the first direction, a distance between a second light-emitting device closest to any one of edges of the substrate and the edge is not greater than the distance between the two adjacent first light-emitting devices; and along the second direction, a distance between a second light-emitting device closest to any one of edges of the substrate and the edge is not greater than the distance between the two adjacent first light-emitting devices.

7. The light-emitting base plate according to claim 2, wherein a brightness of the surrounding region is greater than or equal to 70% of a brightness of the intermediate region.

8. The light-emitting base plate according to claim 7, wherein a brightness difference between the surrounding region and the intermediate region is less than 0.04×10⁷ Lux.

9. The light-emitting base plate according to claim 6, wherein the surrounding region and the intermediate region comprise an integer number of light regions, respectively, and each light region comprises a×b electrically connected light-emitting devices, wherein a and b are positive integers.

10. The light-emitting base plate according to claim 6, wherein the surrounding region and the intermediate region comprise a non-integer number of light regions, respectively, and each light region comprises a×b electrically connected light-emitting devices, wherein a and b are positive integers.

11. A light-emitting apparatus, comprising the light-emitting base plate according to claim 1.

12. The light-emitting apparatus according to claim 11, wherein the light-emitting apparatus further comprises a diffusing plate, a quantum dot film, a diffusion sheet and a composite film sequentially arranged in layer configuration;
wherein the diffusing plate is located at a light-exiting side of the light-emitting base plate.

13. A display apparatus, wherein the display apparatus comprises a display plate and the light-emitting apparatus according to claim 11, the display plate is located at a light-exiting side of the light-emitting apparatus, and light emitted by all the light-emitting devices in the light-emitting apparatus has a same color.

14. The light-emitting apparatus according to claim 11, wherein the surrounding region has a closed outline; a size of the intermediate region along a first direction is X times a size of the surrounding region along the first direction, and a size of the intermediate region along a second direction is X times a size of the surrounding region along the second direction, wherein the first direction and the second direction intersect, and a value of X ranges from 7 to 8.

15. The light-emitting apparatus according to claim 14, wherein the surrounding region is only provided with the second light-emitting devices; along the first direction, a distance between two adjacent first light-emitting devices is greater than or equal to a distance between two adjacent second light-emitting devices; and
along the second direction, a distance between the two adjacent first light-emitting devices is greater than or equal to a distance between the two adjacent second light-emitting devices.

16. The light-emitting apparatus according to claim 15, wherein along the first direction, a distance between a first light-emitting device and a second light-emitting device that are adjacent is less than or equal to the distance between the two adjacent first light-emitting devices; and along the second direction, a distance between a first light-emitting device and a second light-emitting device that are adjacent is less than or equal to the distance between the two adjacent first light-emitting devices.

17. The light-emitting apparatus according to claim 14, wherein the surrounding region is only provided with the second light-emitting devices; along the first direction, a distance between two adjacent first light-emitting devices is less than or equal to a distance between two adjacent second light-emitting devices; and
along the second direction, a distance between the two adjacent first light-emitting devices is less than or equal to a distance between the two adjacent second light-emitting devices.

18. The light-emitting apparatus according to claim 15, wherein along the first direction, a distance between a second light-emitting device closest to any one of edges of the substrate and the edge is not greater than the distance between the two adjacent first light-emitting devices; and along the second direction, a distance between a second light-emitting device closest to any one of edges of the substrate and the edge is not greater than the distance between the two adjacent first light-emitting devices.

19. The light-emitting apparatus according to claim 14, wherein a brightness of the surrounding region is greater than or equal to 70% of a brightness of the intermediate region.

20. The light-emitting apparatus according to claim 19, wherein a brightness difference between the surrounding region and the intermediate region is less than 0.04×10⁷ Lux.
